(19) United States
(12) Patent Application Publication
(10) Pub. No.: US 2015/0255499 A1
(43) Pub. Date: Sep. 10, 2015

(54) CHIP PACKAGE AND METHOD OF FABRICATING THE SAME

(71) Applicant: XINTEC INC., Taoyuan City (TW)

(72) Inventors: Po-Han LEE, Taipei City (TW); Chia-Ming CHENG, New Taipei City (TW); Chien-Hung LIU, New Taipei City (TW)

(21) Appl. No.: 14/621,240

(22) Filed: Feb. 12, 2015

Related U.S. Application Data
(60) Provisional application No. 61/949,595, filed on Mar. 7, 2014.

(51) Int. Cl. H01L 27/146

(52) U.S. Cl. CPC H01L 27/14636; H01L 27/14621; H01L 27/14605; H01L 27/14685

(57) ABSTRACT

A chip package includes a semiconductor chip, insulation layer, redistribution layer and packaging layer and is formed with a cavity. The semiconductor chip has an electronic component and a conductive pad. The conductive pad and the electronic component are disposed on an upper surface of the semiconductor chip and electrically connected. The cavity opens from a lower surface of the semiconductor chip and tapers toward the upper surface to expose the conductive pad. The insulation layer coats the lower surface and a portion of the cavity. The insulation layer is formed with a gap to expose the conductive pad. The redistribution layer coats the lower surface and a portion of the cavity and is electrically connected to the conductive pad through the gap. The packaging layer coats the lower surface and a portion of the cavity.

### RELATED APPLICATIONS

This application claims priority to U.S. Provisional Application No. 61/949,595, filed Mar. 7, 2014, which is herein incorporated by reference.

### BACKGROUND

1. Field of Invention

The present invention relates to a package and method of fabrication the same. More particularly, the present invention relates to a chip package and method of fabrication the same.

2. Description of Related Art

Since electronic products require multifunction and compact at the same time, the corresponding semiconductor chips are minimized and the wire distribution is much denser. As a result, more complex wiring in chip package manufacturing is a great concern in this industry. Wafer-level chip package is a type of semiconductor chip packaging. It refers to after all the chips on the wafer are complete, chip packaging and evaluation are carried out directly, and then each die is cut out. In the case of semiconductor size minimization and high wiring density, chip package design and manufacture process are more complicated. Therefore, the requirement for manufacturing process is higher in response to a higher standard, and it leads to cost increase as well as lower yield rate. A more reliable and suitable method of manufacturing chip package comes to the priority in the industry.

### SUMMARY

The invention provides a chip package and method of fabrication the same. The key packaging stacking, for example, an insulation layer, a redistribution layer and a packaging layer are disposed on one side of the semiconductor chip. In other words, packaging stacking is carried out once on the side of the semiconductor chip, and the electrical conducting passage of the semiconductor chip is complete. It greatly reduces the manufacturing cost of semiconductor chip. Furthermore, the other side of the semiconductor chip is not involved in the packaging stacking, and therefore the other side can be flat surface. Accordingly, the semiconductor chip can be used in optical applications, and upon stacking each semiconductor chip can be piled up more easily.

A chip package in accordance with an embodiment of the instant disclosure is provided. The chip package includes a semiconductor chip, a cavity, a redistribution layer, an insulation layer and a packaging layer. The semiconductor chip has an electronic component and at least one electrically conductive pad. The electrically conductive pad is disposed on an upper surface of the semiconductor chip and electrically connected to the electronic component. The cavity opens to a lower surface and allows contact with the electrically conductive pad. The insulation layer is laminated over the lower surface and the cavity and is formed with a gap exposing the electrically conductive pad. The redistribution layer is laminated the lower surface and a portion of the cavity. The redistribution layer is electrically connected to the electrically conductive pad through the gap. The packaging layer coats the lower surface and a portion of the cavity.

In an embodiment of the instant disclosure, the upper surface of the semiconductor chip is planar.

In an embodiment of the instant disclosure, the cavity is stepwise to form a recession and a passage exposing the electrically conductive pad, and a width of the recession is larger than a width of the passage.

In an embodiment of the instant disclosure, a depth of the recession is larger than a depth of the passage.

In an embodiment of the instant disclosure, a width-depth ratio of the passage is less than 2.

In an embodiment of the instant disclosure, the chip package further includes a soldering ball disposed on the lower surface, and the soldering ball and the redistribution layer are electrically connected.

In an embodiment of the instant disclosure, the electronic component is a photosensitive component.

In an embodiment of the instant disclosure, the chip package further includes a filter layer disposed on the upper surface.

In an embodiment of the instant disclosure, the chip package further includes a wear resistance layer disposed on the upper surface.

In an embodiment of the instant disclosure, the chip package further includes a drain diffusion layer disposed on the upper surface.

A method of fabricating chip package in accordance with an embodiment of the instant disclosure is provided. The method includes providing a semiconductor wafer having at least two semiconductor chips arranged immediately abreast. The semiconductor wafer has an upper surface and a lower surface opposite to the upper surface. At least an electrically conductive pad is disposed on the upper surface of each of the semiconductor chip. Then at least two cavities are formed on each of the two semiconductor chips. The cavities allow contact with the electrically conductive pad. Next, an insulation layer is formed to laminate the lower surface and the cavity. The insulation layer has at least two gaps exposing the electrically conductive pads. Following that, a redistribution layer coating the lower surface and a portion of the cavity is formed. The redistribution layer is electrically connected to the electrically conductive pad through the gaps. Finally, a packaging layer coating the lower surface and a portion of the cavity is formed.

In an embodiment of the instant disclosure, the formation of cavities further includes forming at least two recessions tapering toward the upper surface on the semiconductor chips and forming a passage allowing access to the electrically conductive pad.

In an embodiment of the instant disclosure, the method of fabricating the chip package further includes forming at least two soldering balls on the lower surface of each of the two semiconductor chips. The soldering balls and the redistribution layer are electrically connected.

In an embodiment of the instant disclosure, the soldering balls are made of tin.

In an embodiment of the instant disclosure, the method of fabricating the chip package further includes forming at least two soldering pads on the lower surface of each of the two semiconductor chips. The soldering pads and the redistribution layer are electrically connected. A soldering wire electrically connected to the soldering pad is also formed.

In an embodiment of the instant disclosure, the method of fabricating the chip package further includes forming a passivation layer on the upper surface coating each of the semiconductor chips.

In an embodiment of the instant disclosure, the method of fabricating the chip package further includes forming a drain diffusion layer on the upper surface coating each of the semiconductor chips.

In an embodiment of the instant disclosure, the method of fabricating the chip package further includes cutting the at least two semiconductor chips along a cutting line. The cutting line is arranged between the two semiconductor chips.

In an embodiment of the instant disclosure, the formation of the redistribution layer further includes forming a conductive film on the lower surface and a portion of the cavities and photolithography etching the conductive film to form patterns.

It is to be understood that both the foregoing general description and the following detailed description are by examples and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a partially cross-sectional view of a chip package in accordance with an embodiment of the instant disclosure;

FIG. 2 is a partially cross-sectional view of a chip package in accordance with an embodiment of the instant disclosure;

FIG. 3 is a top view in a stage of a fabrication process in accordance with an embodiment of the instant disclosure;

FIGS. 4 to 7 are cross-sectional views along line 4 in FIG. 3 from different stages of a fabrication process in accordance with an embodiment of the instant disclosure; and

FIGS. 8 to 11 are cross-sectional views along line 4 in FIG. 3 from different stages of a fabrication process in accordance with another embodiment of the instant disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

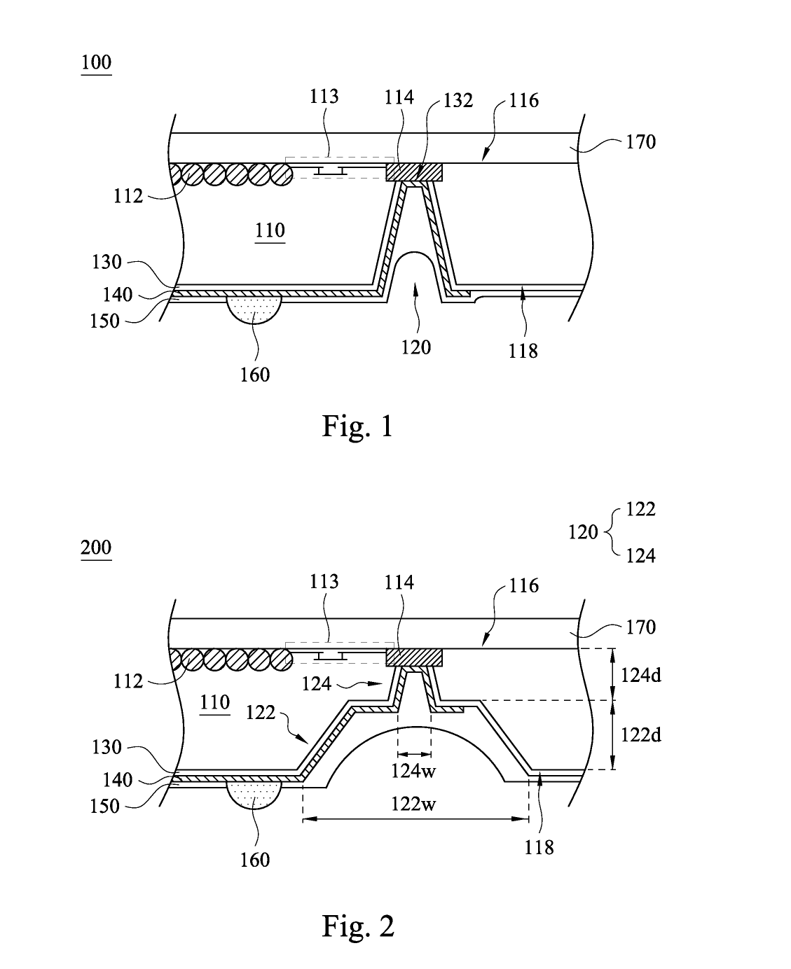

FIG. 1 is a partially cross-sectional view of a chip package in accordance with an embodiment of the instant disclosure. Please refer to FIG. 1. A chip package 100 includes a semiconductor chip 110, a cavity 120, an insulation layer 130, a redistribution layer 140 and a packaging layer 150. The semiconductor chip 110 has an electronic component 112 electrically connected to at least an electrically conductive pad 114. The conductive pad 114 and the electronic component 112 are electrically connected together and disposed on an upper surface 116 of the semiconductor chip 110. The semiconductor chip 110 may be, for example, silicon, germanium or group III-V elements, and the electronic component 112 and the conductive pad 114 are manufactured thereon. In an embodiment of the instant disclosure, the electronic component 112 can be light sensitive component; however, the instant disclosure is not limited thereto. The electronic component 112 can be, for example, active element, passive elements, digital circuit, analogue circuit or other conventional integrated circuit electronic components. Furthermore, the electronic component 112 can be micro electro mechanical systems (MEMS), micro fluidic systems, physical sensor using heat, light and pressure to detect, RF circuits, accelerators, gyroscopes, micro actuators, surface sonic component, pressure sensors or the like. As shown in FIG. 1, the conductive pad 114 is disposed on the upper surface 116 of the semiconductor chip 110, and the electronic component 112 is disposed in the semiconductor chip 110. The conductive pad 114 can be electrically connected to the electronic component 112 by interconnection structure 113. The conductive pad 114 acts as a signal controlling input/output for the electronic component 112 of the semiconductor chip 110. The material of the conductive pad 114 can be aluminum, copper, nickel or any other suitable conductive materials.

Please refer to FIG. 1. The cavity 120 opens at the lower surface 118 and tapers toward the upper surface 116 to expose the conductive pad 114. The cavity 120 is formed by photolithography etching or laser drilling from the lower surface 118 and is directed toward where the conductive pad 114 is disposed. In other words, the cavity 120 provides a passage from the lower surface 118 of the semiconductor chip 110 to the conductive pad 114, which acts as a signal controlling input/output for electronic component 112 of semiconductor chip 110, for electrical connection with the redistribution layer 140. The insulation layer 130 is laminated over the lower surface 118 and a portion of the cavity 120. The insulation layer is discrete to form a gap 132 for exposing the conductive pad 114. The insulation layer 130 can be made of silicon oxide, silicon nitride, silicon oxynitride or any other suitable insulation materials. The insulation layer 130 is deposited by chemical vapor deposition conforming to the lower surface 118 of the semiconductor chip 110, the wall of the cavity 120 and over the top of the conductive pad 114. The conductive pad 114 is then exposed by photolithography etching the insulation layer 130 to form the gap 132. The redistribution layer 140 is laminated over the lower surface 118 and a portion of the cavity 120. The redistribution layer 140 is electrically connected to the conductive pad 114 through the gas 132. The redistribution layer 140 can be made of aluminum, copper or any other suitable conductive materials. The redistribution layer 140 is formed by sputtering or evaporation, conforming to the insulation layer 130 and the conductive pad 114 that is exposed through the gap 132. This thin conductive film is then photolithography etching to form a predetermined pattern of the redistribution layer 140. The packaging layer 150 coats the lower surface 118 and a portion of the cavity 120. The packaging layer 150 can be made of solder mask or any other suitable materials for packaging. The packaging layer 150 is formed on the lower surface 118 of the by sputtering or evaporation and conformingly coats the insulation layer 130 and the redistribution layer 140. As shown in FIG. 1, in an embodiment of the instant disclosure, the chip package 100 further includes a soldering ball 160 disposed on the lower surface 118. The soldering ball 160 can be electrically connected to the redistribution layer 140. The material of the soldering ball 160 may be tin, other suitable soldering metal or alloy. The soldering ball 160 acts as a connection bridge between the chip package 100 and an external printed circuit board or other interposer. Through the soldering ball 160, the input/output signals from the printed circuit board or the interposer are transmitted through the redistribution layer 140 and conductive pad 114 that is electrically connected to the electronic component 112, and therefore the signal input/output of the electronic component 112 of the chip package 100 is controlled. However, the instant disclosure is not limited thereto. In another embodiment of the instant disclosure, the chip package 100 may further include soldering pads and soldering wires connected to the soldering pads. The soldering pads are electrically connected to the redistribution layer 140, and the soldering wires act as bridge between the chip package 100 and external printed circuit board or interposer. The electric signals from the printed circuit board or interpose can be transmitted from the soldering pads and the soldering wires connected thereto, to the redistribution layer 140 and the conductive pad 114 that is electrically connected to the electronic component 112. As a result, signal output/input of the electronic component 112 of the chip package 100 can be controlled.

It should be noted that the conductive pad 114 of the chip package 100 is disposed on the upper surface 116 of the semiconductor chip 110, while the insulation layer 130, redistribution layer 140 and packaging layer 150 coat the lower surface 118 and a portion of the cavity 120. In other words, the insulation layer 130, redistribution layer 140 and packaging layer 150 are formed on a single side (i.e. the lower surface 118) of the semiconductor chip 110. The etching or laser drilling of the cavity 120 is also carried out from the lower surface 118. The deposition and photolithography etching of the insulation layer 130 and redistribution layer 140 are carried out once at the lower surface 118 of the semiconductor chip 110, and the electrical path of the conductive pad 114 disposed on the upper surface 116 is complete. The regulation of signal output/input of the electronic component 112 of the chip package 100 is then controlled. Accordingly, the simplified structure of the chip package 100 significantly reduces the manufacturing cost. More importantly, the cavity 120, insulation layer 130, redistribution layer 140, packaging layer 150 of the chip package 100 are arranged over the lower surface 118 of the semiconductor chip 110. That is to say, the upper surface 116 is intact from the abovementioned elements such that the upper surface 116 can retain its integrity in the manufacturing process. In another embodiment of the instant disclosure, the upper surface 116 of the semiconductor chip 110 is a flat surface, and therefore other processing related to the upper surface 116 of the semiconductor chip 110 can be simplified. For example, the chip package 100 may further include a passivation layer disposed on the upper surface 116 of the semiconductor chip 110 so as to isolate air or act as a buffer to protect the electronic component 112, conductive pad 114 and the interconnection structure 113 within the semiconductor chip 110. The passivation layer can be made of silicon oxide, silicon nitride, silicon oxynitride or the like. As shown in FIG. 1, in an embodiment of the instant disclosure, the electronic component 112 is a light sensitive element. The chip package 100 may further include a filter layer 170 disposed on the upper surface 116. The filter layer 170 is a thin film specific to different light wavelength in association with the light sensitive element. In another embodiment of the instant disclosure, the chip package 100 may further include a wear resistance layer disposed on the upper surface 116. The wear resistance layer may be made of sapphire or any other materials exhibiting higher degree of hardness so as to protect the electronic component 112, conductive pad 114 and the interconnection structure 113 within the semiconductor chip 110. In another embodiment of the instant disclosure, the chip package 100 may further include a drain diffusion layer disposed on the upper surface 116. The drain diffusion layer may be made of polytetrafluoroethylene (PTFE), polyester, polyolefin, polydimethylsiloxane or other suitable drainage materials to effectively block moisture such that the chip package 100 can be more reliable. In addition, in the chip package 100, the upper surface 116 of the semiconductor chip 110 is spared from the formation of cavity 120, insulation layer 130, redistribution layer 140 and packaging layer 150. Therefore, in the packaging process, the chip package 100 does not need to be turned over such that the temporary attachment materials used in flipping are not required, and thus the manufacture cost is reduced.

FIG. 2 is a partially cross-sectional view of a chip package in accordance with an embodiment of the instant disclosure. Please refer to FIG. 2. The chip package 200 includes a semiconductor chip 110, a cavity 120, an insulation layer 130, a redistribution layer 140 and a packaging layer 150. The semiconductor chip 110, insulation layer 130, redistribution layer 140 and packaging layer 150 are similar to those in the previous embodiment of chip package 100 and herein omitted to avoid redundancy. As shown in FIG. 2, the difference between the chip package 200 and the chip package 100 in FIG. 1 arises from the cavity 120. The cavity 120 of the chip package 200 has stepwise configuration including a depression 122 and a passage 124. The depression 122 opens at the lower surface 118 and reduces toward the upper surface 116. The passage 124 further reduces from the depression 122 toward the upper surface 116 and allows access to the conductive pad 114. It should be noted that the width 122w of the depression 122 is larger than the width 124w of the passage 124. In other words, the cavity 120 of the chip package 200 is formed by slanting and stepwise structure of a wider opening depression 122 and a narrower passage 124. Compared with the chip package 100 in FIG. 1, the configuration of the cavity 120 of the chip package 200 allows easier deposition of the films. In the process of film deposition, different trench depth, opening size and depth-width ratio have critical impact on gap-fill capability. In general, the smaller the opening size of higher the depth-width ratio, the higher gap-fill capability is required. Therefore, when the insulation layer 130, redistribution layer 140 and the packaging layer 150 are formed from the lower surface 118 along the wall of the cavity 120, the wide opening of the cavity 120 allows easier film deposition. In particular, the redistribution layer 140 can be laminated on the wall of the cavity 120 (including the depression 122 and the passage 124) much easier so as to ensure the electrical connection among electronic component 112 within the semiconductor chip 110, conductive pad 114 and interconnection structure 113 and minimize the chance of wire breaking. In an embodiment of the instant disclosure, the depth 122d of the depression 122 is larger than the depth 124d of the passage 124. Thus, the passage 124 has smaller opening and depth 124d such that the aspect ration of the passage 124 is reduced. In this regard, the redistribution layer 140 can be easily deposited alone the wall of the cavity 120 (including the depression 122 and the passage 124). The occurrence of wire breaking can be minimized because the electrical connection among electronic component 112 within the semiconductor chip 110, conductive pad 114 and interconnection structure 113 are better secured. In an embodiment of the instant disclosure, the aspect ratio (124d against 124w) of the passage 124 is less than 2. That is to say, the depth 124d of the passage 124 will not be larger than twice of the width 124w of the passage 124. Accordingly, the requirement of gap-fill capability is further reduced for the insulation layer 130, redistribution layer 140 and packaging layer 150. The film formation has a higher yielding rate on the wall of the cavity 120, and the manufacturing cost goes down as well.

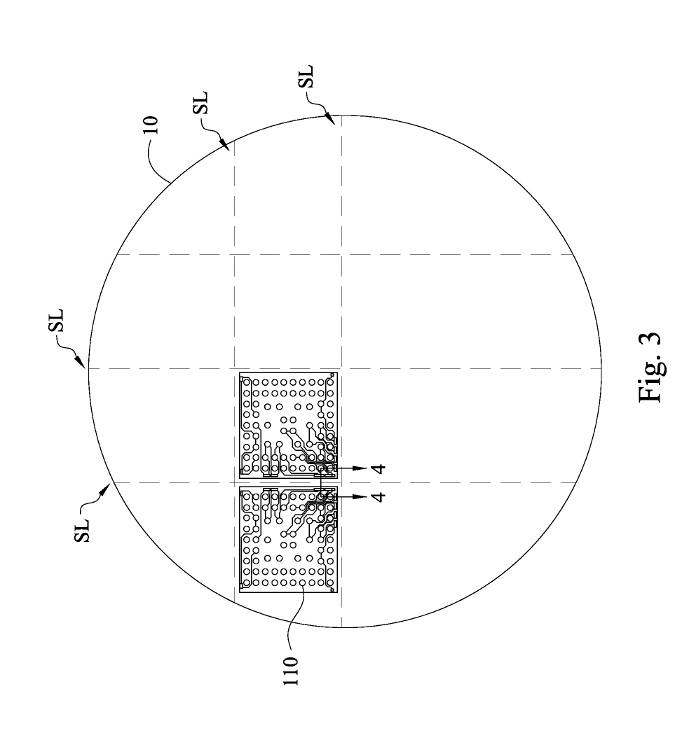

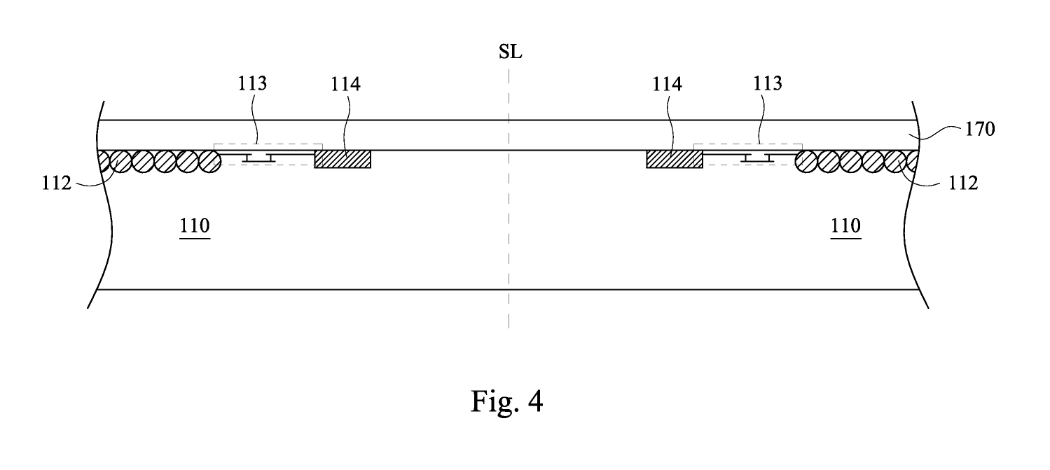

FIG. 3 is a top view in a stage of a fabrication process in accordance with an embodiment of the instant disclosure. FIG. 4 is a partially cross-sectional view along line 4 in FIG. 3 in a stage of the fabrication process in accordance with an embodiment of the instant disclosure. FIGS. 4 to 7 are cross-sectional views along line 4 in FIG. 3 from different stages of the fabrication process in accordance with an embodiment of the instant disclosure. Please refer to FIG. 3. A semiconductor wafer 10 is provided, and the semiconductor wafer 10 includes at least two semiconductor chips 110 immediately abreast. The semiconductor wafer 10 can be made of, for example, silicon, germanium, group III-V elements or the like. A plurality of semiconductor chips 110 is arranged abreast on the semiconductor wafer 10. Each of the chips 110 has the same electronic components and conductive pads as mentioned previously. As shown in FIG. 3, the boarder of each of the semiconductor chips 110 is determined by a cutting line SL. Please refer to FIG. 4. The semiconductor wafer 10 has an upper surface (i.e. the upper surface 116 of each of the semiconductor chips 110) and a lower surface (i.e. the lower surface 118 of each of the semiconductor chips 110), and each of the semiconductor chips 110 has at least one conductive pad 114 on the upper surface 116 on at least one side. The conductive pad 114 can be, for example, electrically connected to the electronic component 112 through the interconnection structure 113. In the semiconductor chip 110, the conductive pad 114 acts as signal controlling input/output of the electronic component 112.

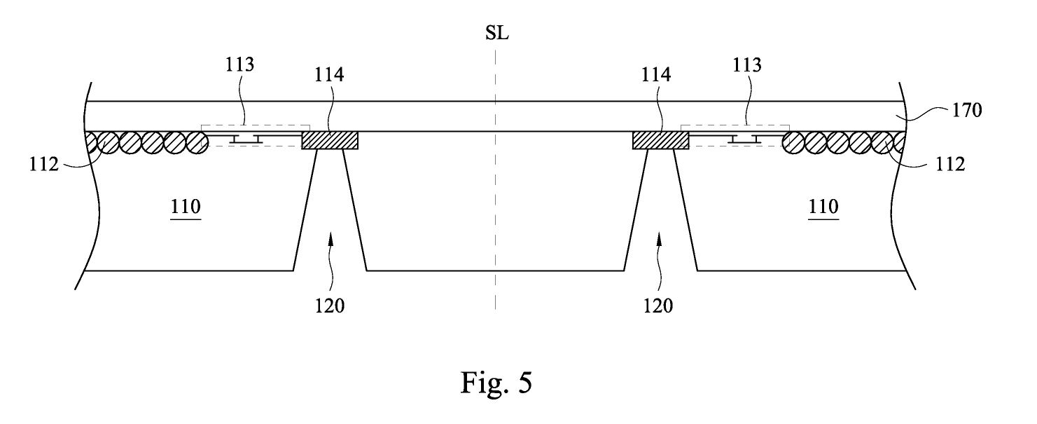

FIG. 5 is a partially cross-sectional view along line 4 in FIG. 3 in a stage of the fabrication process. At least two cavities 120 are formed on at least two chips 110. Each of the cavities 120 opens at the lower surface 118 and reduces toward the upper surface 116 to expose each of the conductive pads 114. The cavity 120 can be formed by photolithography etching or laser drilling; however, the instant disclosure is not limited thereto. As mentioned previously, the conductive pad 114 acts as the signal controlling input/output between external component and the electronic component 112 of the semiconductor chip 110. Therefore when undergoing etching or drilling from the lower surface 118 toward the upper surface 116, the etching or drilling end point is determined by where the conductive pads 114 of each of the semiconductor chips 110 are exposed.

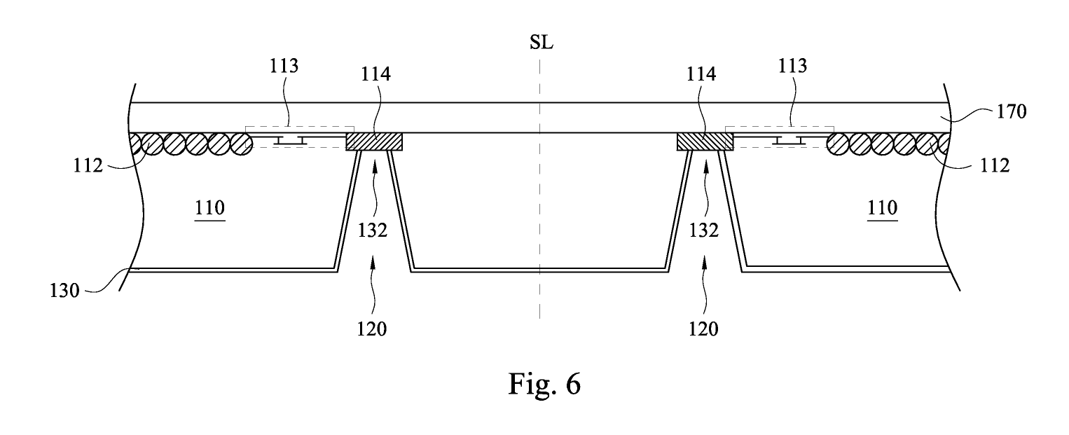

FIG. 6 is a partially cross-sectional view alone line 4 in FIG. 3 in a stage of the fabrication process. After the formation of the cavities 120, an insulation layer 130 is laminated on the lower surface 18 toward the upper surface 116 and a portion of the wall of the cavities 120. The insulation layer 130 is formed with at least two gaps 132 to expose the conductive pads 114. The insulation layer 130 can be made of silicon oxide, silicon nitride, silicon oxynitride or any other suitable insulation materials. The insulation layer 130 is deposited by chemical vapor deposition conforming to the lower surface 118 of the semiconductor chip 110, the wall of the cavity 120 and over the top of the conductive pad 114. The conductive pad 114 is then exposed by photolithography etching the insulation layer 130 to form the gaps 132. Next, the redistribution layer 140 is laminated on the lower surface 118 and a portion of the wall of the cavity 120. The redistribution layer 140 is electrically connected to each of the conductive pads 114 through the gap 132. The material of the redistribution layer can be, for example, aluminium, copper, conductive high molecule or any other suitable conductive materials. In an embodiment of the instant disclosure, the formation of the redistribution layer includes coating the lower surface 118 with the conductive film all the way to the upper surface 116 and a portion of the wall of the cavity 120. Then the conductive film is patterned by photolithography etching. In other words, the conductive film is conformingly deposited over the insulation layer 130 and the conductive pad 114 exposed on the gap 132 by spluttering, evaporation, spin coating or the like. Following that, the conductive film is patterned by photolithography etching to form the redistribution layer 140 with a predetermined pattern.

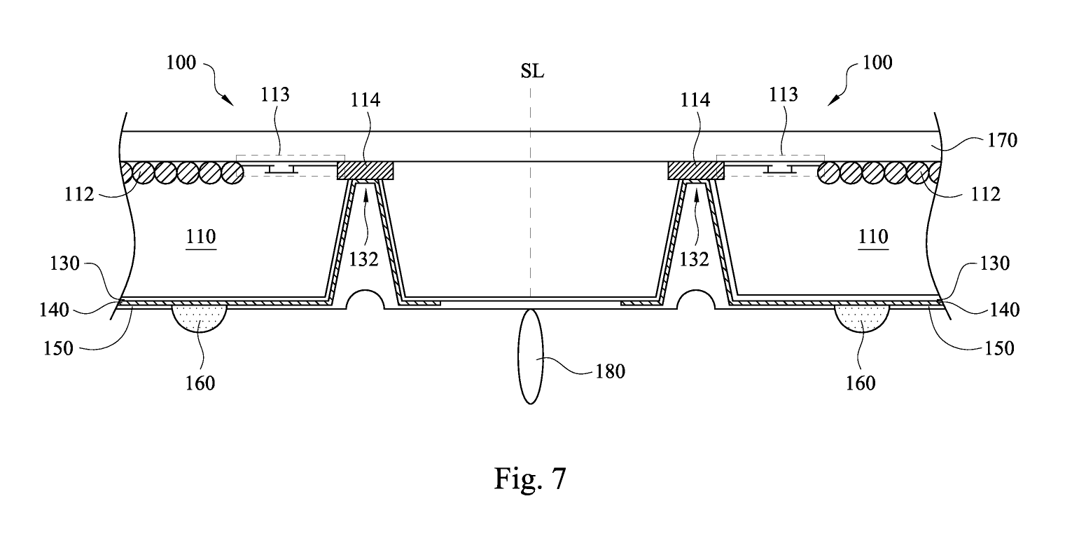

FIG. 7 is a partially cross-sectional view alone line 4 in FIG. 3 in a stage of the fabrication process. After the formation of the redistribution layer 140, the packaging layer 150 is formed on the lower surface 118 toward the upper surface 116 and a portion of the wall of the cavity 120. The packaging layer 150 can be formed by brush coating or spin-coating the solder mask, and the instant disclosure is not limited thereto. As shown in FIG. 7, in an embodiment of the instant disclosure, the method of fabricating the chip package further includes the formation of at least two soldering balls 160. Each of the soldering balls 160 is disposed on the lower surface 118 of one semiconductor chip. The soldering balls 160 are electrically connected to the redistribution layer 140. The soldering ball 160 can be made of tin or any other metal or metal alloy suitable for soldering and formed by coating or film deposition along with photolithography etching. In an embodiment of the instant disclosure, the soldering ball is made of tin. Output/input signals from a printed circuit board or other interposer can be transmitted through the soldering ball 160 to the redistribution layer 140 and to the conductive pad 114 that is electrically connected to the electronic component 112. In this way, the output/input signal of the electronic component 112 within the semiconductor chip 110 is regulated by the printed circuit board or the interposer. However, the instant disclosure is not limited thereto. In an embodiment of the instant disclosure, the method of fabricating chip package further includes the formation of at least two soldering pads. Each of the soldering pads is disposed on the lower surface 118 of one semiconductor chip 110. The soldering pads are electrically connected to the redistribution layer 140, and soldering wires are formed and electrically connected to the soldering pads. Because the soldering pads and the redistribution layer 140 is electrically connected, the soldering wires act as a connection bridge between the chip package and external printed circuit board or interposer. The input/output signals from the printed circuit board or interposer can be transmitted through the soldering pads, soldering wires, redistribution layer 140 and the conductive pads 114 that is connected to the electronic component 112. Accordingly, the input/output signals of the electronic component 112 within the semiconductor 110 can be controlled by the external printed circuit board or interposer. As shown in FIGS. 3 and 7, in an embodiment of the instant disclosure, the method of fabricating the chip package further includes dicing the semiconductor chip 110 along a cutting line SL. The cutting line SL is arranged between each of the semiconductor chips 110. As shown in FIG. 7, the method of cutting may be slicing along the cutting line SL by a cutting knife 180 to separate two abreast semiconductor chips 110. The chip package 100 in FIG. 1 is then complete.

It should be noted that in the method of fabricating chip package the insulation layer 130, redistribution layer 140 and packaging layer 150 coat the lower surface 118 and a portion of the wall of the cavity 120. In other words, the insulation layer 130, redistribution layer 140 and packaging layer 150 are formed on a single side (i.e. the lower surface 118) of the semiconductor chip 110. The etching or laser drilling of the cavity 120 is also carried out from the lower surface 118. The deposition and photolithography etching of the insulation layer 130 and redistribution layer 140 are carried out once at the lower surface 118 of the semiconductor chip 110, and the electrical path of the conductive pad 114 disposed on the upper surface 116 is complete. Accordingly, the method of fabricating chip package saves the production cost in the process. In addition, the upper surface 116 is intact from the abovementioned elements such that the upper surface 116 can retain its integrity in the manufacturing process. In an embodiment of the instant disclosure, the electronic component 112 is a light sensitive element. The method may further include a filter layer 170 disposed on the upper surface 116 and coats each of the semiconductor chips 110. The filter layer 170 is a thin film specific to different light wavelength in association with the light sensitive element. In an embodiment of the instant disclosure, the method of fabricating chip package may further include the formation of a passivation layer on the upper surface 116 of the semiconductor chip 110 so as to isolate air or act as a buffer to protect the electronic component 112, conductive pad 114 and the interconnection structure 113 within the semiconductor chip 110. The passivation layer can be made of silicon oxide, silicon nitride, silicon oxynitride or the like. In an embodiment of the instant disclosure, the method of fabricating chip package further includes the formation of a wear resistance layer on the upper surface 116. The wear resistance layer may be made of sapphire or any other materials exhibiting higher degree of hardness so as to protect the electronic component 112, conductive pad 114 and the interconnection structure 113 within the semiconductor chip 110. In another embodiment of the instant disclosure, the method of fabricating chip package further includes the formation of a drain diffusion layer on the upper surface 116. The drain diffusion layer may be made of polytetrafluoroethylene (PTFE), polyester, polyolefin, polydimethylsiloxane or other suitable drainage materials to effectively block moisture such that the chip package can be more reliable.

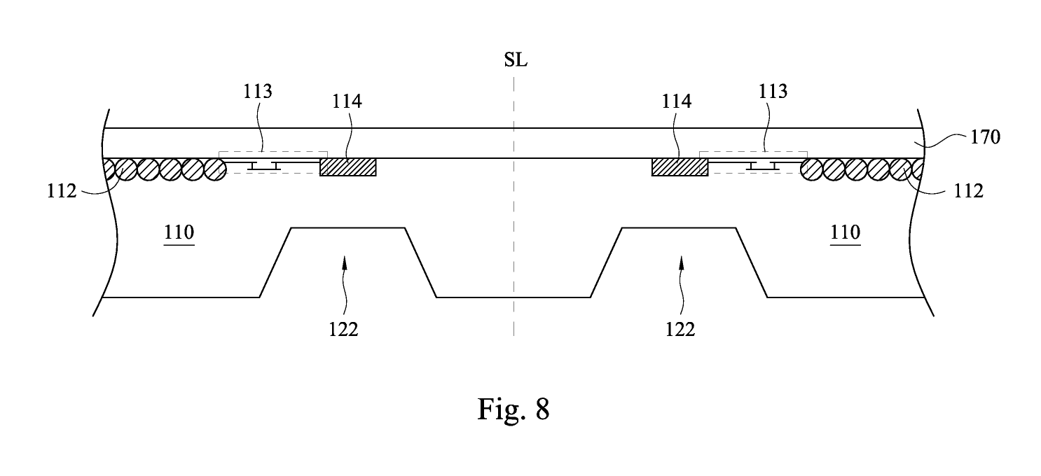

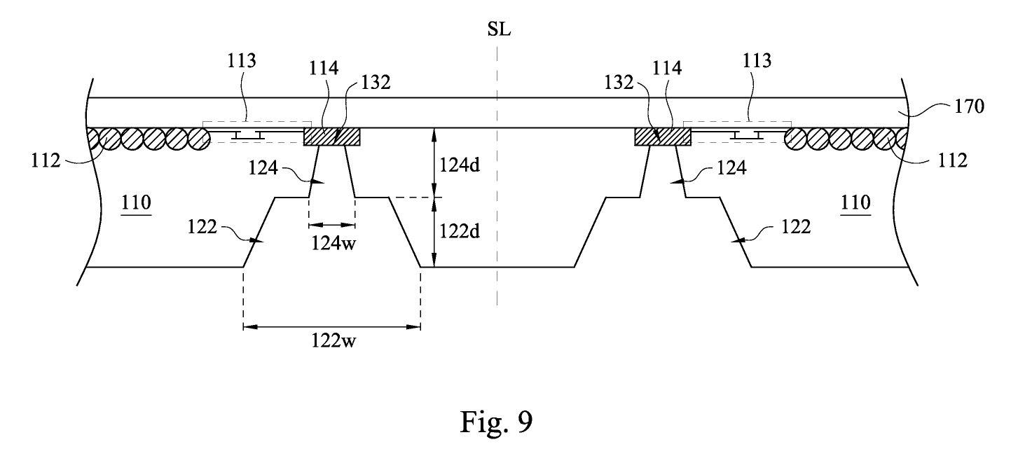

FIGS. 8 to 11 are cross-sectional views along line 4 in FIG. 3 from different stages of a fabrication process in accordance with another embodiment of the instant disclosure. Please refer to FIG. 8. In an embodiment of the instant disclosure, the formation of the cavity 120 includes the formation of at least two depressions 122. Each of the depressions 122 corresponds to one of the semiconductor chips 110. The depression 122 opens to the lower surface 118 and tapers toward the lower surface 116. The formation of the depression 122 may be photolithography etching or laser drilling from the lower surface 118 toward the upper surface 116, aiming to the position of the conductive pad 114 of the semiconductor chip 110. It should be noted that the depression 122 does not go through the upper surface 116, and therefore the conductive pad 114 of the semiconductor chip 110 is not exposed from the depression 122. Next please refer to FIG. 9. a passage 124 is formed in succession to the depression 122 toward the upper surface 116 to expose the conductive pad 114. The formation of the passage 124 may be photolithography etching or laser drilling. As mentioned previously, the conductive pad 114 acts as the signal controlling input/output between external component and the electronic component 112 of the semiconductor chip 110. Therefore when undergoing etching or drilling from the lower surface 118 toward the upper surface 116, the etching or drilling end point is determined by where the conductive pad 114 of each of the semiconductor chips 110 is exposed. The difference between this stepwise configuration and the method shown in FIGS. 5 to 7 is that the cavity 120 is formed in two stages. In more detail, the depression 122 is formed first and then the passage 124 to expose the conductive pad 114. In this regard, the chance of cavity 120 and conductive pad 114 being mis-positioned can be reduced. The yield rate of cavity 120 is improved thereby, and the production cost is reduced at the same time. In addition, since passage 124 is formed by further etching or drilling from the depression 122, in an embodiment of the instant disclosure, the width 122w of the depression 122 is larger than the width 124w of the passage 124. Compared to the method shown in FIGS. 5 to 7, the film can be deposited in the depression and passage much easier. In other words, for the films coating the lower surface 118 and a portion of the wall of the cavity 120 like the insulation layer 130, redistribution layer 140 and the packaging layer 150, it is easier to coat the wall of the cavity 120. Especially to the redistribution layer 140, the redistribution layer 140 can be deposited along the wall of the cavity 120 (including the depression 122 and passage 124), and wire breakage, which may interrupt the electrical path, is less likely to happen between the electronic component 122, conductive pad 114 and interconnection structure 113 within the semiconductor chip 110. In another embodiment of the instant disclosure, the depth of the depression 122 is adjustable when etching or drilling such that the depth 122d of the depression 122 is larger than the depth 124d of the passage 124. In more detail, the passage 124 has smaller opening and shallower depth 124d. The aspect ratio of the passage 124 decreases such that the redistribution layer 140 can be easily deposited in the cavity 120 (including the depression 122 and the passage 124), and wire breakage, which may interrupt the electrical path, is less likely to happen between the electronic component 122, conductive pad 114 and interconnection structure 113 within the semiconductor chip 110. In another embodiment of the instant disclosure, the depth and width of the depression 122 and passage 124 is adjustable according to the requirement. The aspect ratio (124d against 124w) of the passage 124 may be less than 2. That is to say, the depth 124d of the passage 124 will not be larger than twice of the width 124w of the passage 124. Accordingly, the requirement of gap-fill capability is further reduced for the insulation layer 130, redistribution layer 140 and packaging layer 150. The film formation has a higher yielding rate on the wall of the cavity 120, and the manufacturing cost goes down as well.

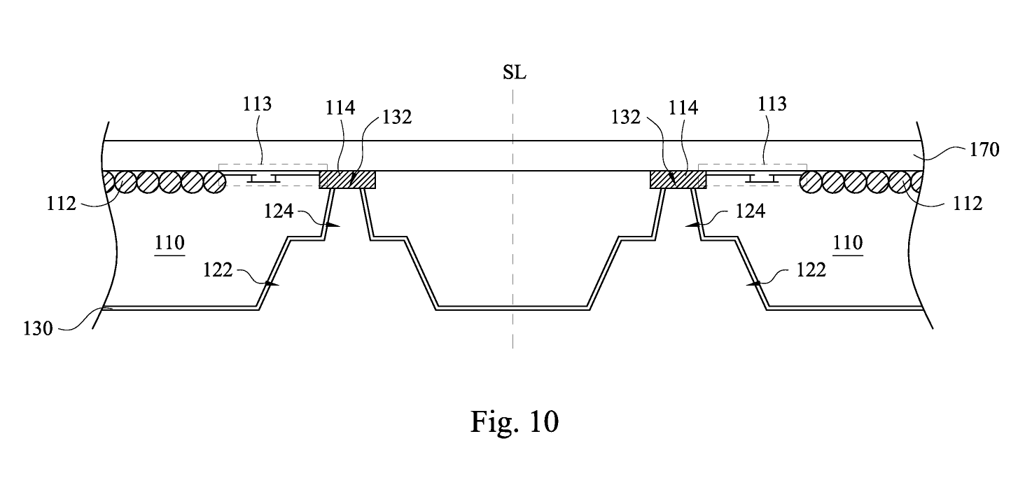

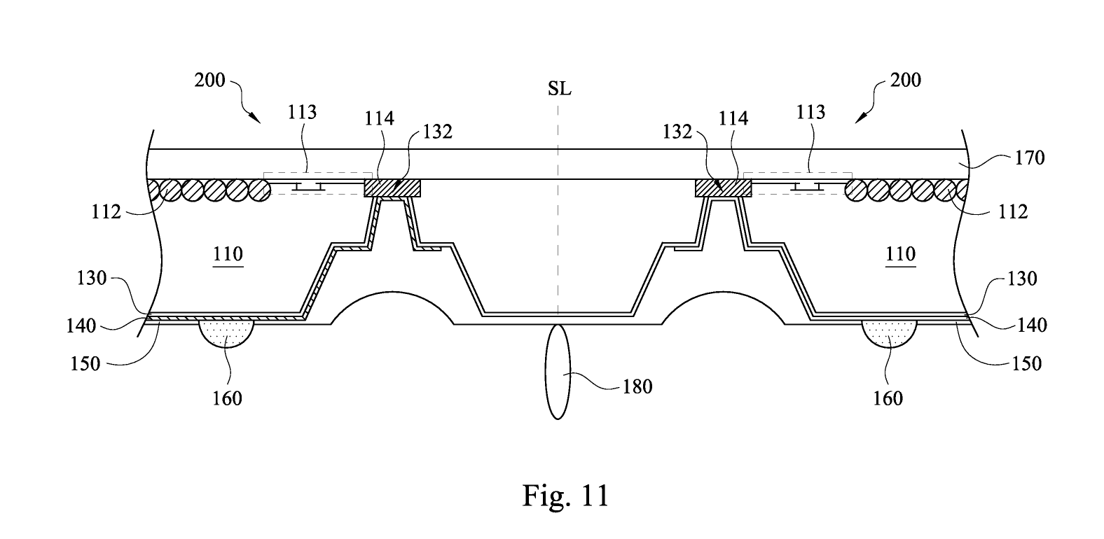

Please refer to FIG. 10. The insulation layer 130 is formed on the lower surface 118 and a portion of the wall of the cavity 120. The insulation layer 130 is formed with at least two gaps 132 to expose the conductive pads 114. The material and method of making the insulation layer 130 is similar to the abovementioned and is omitted herein. Please refer to FIG. 11. The redistribution layer 140 is formed on the lower surface 118 and a portion of the wall of the cavity 120. The redistribution layer 140 is electrically connected to each of the conductive pads 114 through the gaps 132. The material and method of making the redistribution layer 140 is similar to the abovementioned and is omitted herein. After the formation of the redistribution layer 140, the packaging layer 150 is formed on the lower surface 118 and a portion of the wall of the cavity 120. In an embodiment of the instant disclosure, the method of fabricating chip package further includes the formation of at least two soldering balls 160. Each of the soldering balls 160 is disposed on the lower surface 118 of one of the semiconductor chips 110. The soldering balls 160 are electrically connected to the redistribution layer 140. The materials and method of making the packaging layer 150 and the soldering ball 160 are similar to the abovementioned and are omitted herein. The input/output signals are transmitted through the soldering ball 160, redistribution layer 140 and the conductive pad 114 that is electrically connected to the electronic component 112 such that the signal input/output regulation of the electronic component 112 within the semiconductor chip 110 can be controlled. However, the instant disclosure is not limited thereto. In an embodiment of the instant disclosure, the method of fabricating chip package may further include the formation of at least two soldering pads, disposed on the lower surface 118, each corresponding to one of the semiconductor chips 110. The soldering pads are electrically connected to the redistribution layer 140, and the soldering wires are formed to be electrically connected with the soldering pads. The soldering pads and the redistribution layer 140 are electrically connected, and the soldering wires act as bridge between the chip and an external printed circuit board and any other interposer. The input/output signals from the printed circuit board or interposer can be transmitted through the soldering pads, soldering wires, redistribution layer 140 and the conductive pads 114 that is connected to the electronic component 112. Accordingly, the input/output signals of the electronic component 112 within the semiconductor 110 can be controlled by the external printed circuit board or interposer. As shown in FIGS. 3 and 11, in an embodiment of the instant disclosure, the method of fabricating the chip package further includes dicing the semiconductor chip 110 along a cutting line SL. The cutting line SL is arranged between each of the semiconductor chips 110. As shown in FIG. 11, the method of cutting may be slicing along the cutting line SL by a cutting knife 180 to separate two abreast semiconductor chips 110. The chip package 200 in FIG. 2 is then complete.

In summary, the instant disclosure provides a chip package and a method of making the same. The conductive pad of the chip package is disposed on the upper surface of the semiconductor chip, while the cavity opens to the lower surface and the insulation layer, redistribution layer, packaging layer are formed on the lower surface extending toward the upper surface. Therefore upper components are fabricated on a single side of the semiconductor chip to complete the electrical path of the conductive pad on the surface of the semiconductor chip. In this regard, the manufacturing cost is greatly reduced. More importantly, the upper components do not interfere with the upper surface of the semiconductor chip, and therefore the upper surface can retain its integrity in the fabrication. Furthermore, the upper surface of the semiconductor chip may be a flat surface such that its optical application is broader, and alternatively it allows easier piling of other chip packages. In addition, turning over of the chip package is not required such that the temporary attachment when flipping can be omitted. The manufacturing cost is further reduced. In an embodiment of the instant disclosure, the specialized cavity of the chip package allows easier deposition of films. In particular, the redistribution layer can be deposited in the depression and passage and maintain good electrical connection between the electronic component and the conductive pad within the semiconductor chip. Moreover, the requirement of gap-filling capability of the insulation layer, redistribution layer and packaging layer is reduced such that the film yield rate increases as well while the manufacturing cost decreases.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A chip package, comprising:
a semiconductor chip having an electronic component and at least one electrically conductive pad, the electrically conductive pad disposed on an upper surface of the semiconductor chip and electrically connected to the electronic component;
a cavity opening to a lower surface and allowing contact with the electrically conductive pad;
an insulation layer coating the lower surface and a portion of a wall of the cavity and formed with a gap exposing the electrically conductive pad;
a redistribution layer coating the lower surface and a portion of the cavity, the redistribution layer being electrically connected to the electrically conductive pad through the gap; and
a packaging layer coating the lower surface and a portion of the cavity.

2. The chip package of claim 1, wherein the upper surface of the semiconductor chip is planar.

3. The chip package of claim 1, wherein the cavity is stepwise to form a recession and a passage exposing the electrically conductive pad, and a width of the recession is larger than a width of the passage.

4. The chip package of claim 3, wherein a depth of the recession is larger than a depth of the passage.

5. The chip package of claim 4, wherein a width-depth ratio of the passage is less than 2.

6. The chip package of claim 1, further comprising a conductive structure disposed on the lower surface, wherein the conductive structure and the redistribution layer are electrically connected.

7. The chip package of claim 1, wherein the electronic component is a photosensitive component.

8. The chip package of claim 7, further comprising:
a filter layer disposed on the upper surface.

9. The chip package of claim 1, further comprising:
a wear resistance layer disposed on the upper surface.

10. The chip package of claim 1, further comprising:
a drain diffusion layer disposed on the upper surface.

11. A method of fabricating chip package, comprising:
providing a semiconductor wafer having at least two semiconductor chips arranged immediately abreast, the semiconductor wafer having an upper surface and a lower surface opposite to the upper surface, at least an electrically conductive pad disposed on the upper surface of each of the semiconductor chip;
forming at least two cavities, each of which on one of the two semiconductor chips, the cavities allowing contact with the electrically conductive pad;
forming an insulation layer coating the lower surface and a portion of a wall of the cavity, wherein the insulation layer has at least two gaps exposing the electrically conductive pads;
forming a redistribution layer coating the lower surface and a portion of the cavity, wherein the redistribution layer is electrically connected to the electrically conductive pad through the gaps; and
forming a packaging layer coating the lower surface and a portion of the cavity.

12. The method of fabricating chip package of claim 11, wherein the forming of cavities further comprises:
forming at least two recessions tapering toward the upper surface of the semiconductor chips; and
forming a passage allowing access to the electrically conductive pad.

13. The method of fabricating chip package of claim 11, further comprising:
forming at least two conductive structures on the lower surface, each of which on one of the two semiconductor chips, wherein the conductive structures and the redistribution layer are electrically connected.

14. The method of fabricating chip package of claim 13, wherein the conductive structure is made of tin.

15. The method of fabricating chip package of claim 11, further comprising:
forming at least two soldering pads on the lower surface, each of which on one of the two semiconductor chips, wherein the soldering pads and the redistribution layer are electrically connected; and
forming a soldering wire electrically connected to the soldering pad.

16. The method of fabricating chip package of claim 11, further comprising:
forming a passivation layer on the upper surface coating each of the semiconductor chips.

17. The method of fabricating chip package of claim 11, further comprising:
forming a drain diffusion layer on the upper surface coating each of the semiconductor chips.

18. The method of fabricating chip package of claim 11, further comprising:
forming a filter layer on the upper surface coating each of the semiconductor chips.

19. The method of fabricating chip package of claim 11, further comprising:
cutting the at least two semiconductor chips along a cutting line, wherein the cutting line is arranged between the two semiconductor chips.

20. The method of fabricating chip package of claim 11, wherein the forming of the redistribution layer further comprises:
forming a conductive film on the lower surface and a portion of the cavities; and
photolithography etching the conductive film to form patterns.

21. The chip package of claim 6, wherein the conductive structure is made of tin.
